(19) United States
(12) Patent Application Publication
(10) Pub. No.: US 2023/0253754 A1
(43) Pub. Date: Aug. 10, 2023

(54) LASER DEVICE INCLUDING A SCREENING ELEMENT

(71) Applicant: ams-OSRAM International GmbH, Regensburg (DE)

(72) Inventors: Jörg Erich SORG, Regensburg (DE); Markus Reinhard HORN, Bayerbach bei Ergoldsbach (DE); Jan SEIDENFADEN, Neumarkt i. d. Oberpfalz (DE); Harald KÖNIG, Bernhardswald (DE)

(73) Assignee: ams-OSRAM International GmbH, Regensburg (DE)

(21) Appl. No.: 18/004,498

(22) PCT Filed: Jul. 7, 2021
(86) PCT No.: PCT/EP2021/068763

§ 371 Date: Jan. 6, 2023

(30) Foreign Application Priority Data
Jul. 9, 2020 (DE) 10 2020 118 159.0

(51) Int. Cl. H01S 5/02235

(52) U.S. Cl. CPC H01S 5/02235; H01S 5/02255

(57) ABSTRACT

The invention relates to a laser device which includes at least one laser diode having an emission surface via which the laser diode can emit laser light during operation, and a screening element having an entry surface facing the emission surface.

### CROSS REFERENCE TO RELATED APPLICATIONS

This patent application is a national stage entry from International Application No. PCT/EP2021/068763, filed on Jul. 7, 2021, published as International Publication No. WO 2022/008565 A1 on Jan. 13, 2022, and claims priority under 35 U.S.C. § 119 from German patent application 10 2020 118 159.0, filed Jul. 9, 2020, all of which are incorporated by reference herein in their entireties.

### FIELD

A laser apparatus is specified.

### BACKGROUND

It is at least one object of specific embodiments to specify a laser apparatus.

This object is achieved by subject matter according to the independent patent claim. Advantageous embodiments and developments of the subject matter are characterized in the dependent claims and are furthermore evident from the following description and the drawings.

### SUMMARY

According to at least one embodiment, a laser apparatus comprises at least one semiconductor laser diode, which can here and below also be referred to for short as laser diode or laser. The laser diode, which is designed with particular preference as a laser diode chip, is provided and set up to emit during operation light that is laser light at least when specific threshold conditions are exceeded. Accordingly, the semiconductor laser diode during normal operation preferably emits laser light, which for short can also simply be referred to as light.

The laser diode has at least one active layer, which is set up and provided to generate light during operation in at least one active region. The laser diode can emit the laser light during operation for example continuously or, alternatively, also in a pulsed manner. The active layer can in particular be part of a semiconductor layer sequence having a plurality of semiconductor layers and have a main plane of extent which is perpendicular to an arrangement direction of the layers of the semiconductor layer sequence. For example, the active layer can have exactly one active region. The laser diode can furthermore have a plurality of active regions and be designed as what is known as a broad stripe laser. For example a semiconductor layer sequence or at least one active layer based on InₓGa_{y}Al_{1-x-y}As is suitable for long-wave infrared to red radiation, for example a semiconductor layer sequence or at least one active layer based on InₓGa_{y}Al_{1-x-y}P is suitable for red to yellow radiation, and for example a semiconductor layer sequence or at least one active layer on the basis of InₓGa_{y}Al_{1-x-y}N is suitable for short-wave visible radiation, that is to say in particular in the range from green to blue light, and/or for UV radiation, wherein in each case 0≤x≤1, 0≤y≤1 and x+y≤1.

The at least one laser diode can preferably be an edge-emitting semiconductor laser. Alternatively, the at least one laser diode can also be a vertically emitting laser diode, also referred to as VCSEL (“vertical-cavity surface-emitting laser”).

According to a further embodiment, the laser diode has a coupling-out side and a rear side located opposite the coupling-out side. The coupling-out side and the rear side in an edge-emitting semiconductor laser can be in particular side surfaces of the laser diode, with particular preference side surfaces of the semiconductor layer sequence, which can also be referred to as facets. During operation, the laser diode can emit the laser light produced in the active region via the facet on the coupling-out side. Suitable optical coatings, in particular reflective or partially reflective layers or layer sequences, which form an optical resonator for the light generated in the active layer, can be applied on the coupling-out side and the rear side. If the laser diode is a VCSEL, the coupling-out side can be formed by a top side for which corresponding features can apply.

The laser diode can in particular have an emission surface on the coupling-out side, from which the light generated during operation can exit the laser diode. The emission surface can also be referred to as light exit surface or light exit facet. The emission surface in particular forms an interface of the laser diode with which the laser diode adjoins a surrounding medium, which is not an integral part of the laser diode. The surrounding medium that adjoins the emission surface and with which the emission surface is thus in direct contact, can particularly preferably be air, in particular air of the atmosphere surrounding the laser apparatus. The emission surface can be formed for example by a surface of the semiconductor layer sequence or by a surface of a coating on the semiconductor layer sequence, which is an integral part of the laser diode.

Edge-emitting semiconductor lasers, for example, have high beam divergences at the light exit facet. In connection with the high energy densities, this produces high field strengths. The high field strength can ensure material transport of molecules and particles from a, for example gaseous, environment of the laser diode to the laser facet. This effect is referred to as “optical tweezers effect”. In short, the optical tweezers effect thus involves molecules and particles being drawn into a divergent light beam and being transported to the location of maximum irradiance, wherein the effect can be more pronounced in the case of a greater divergence. The material transport to the facet can result in deposits at the location of the greatest illuminance, which can lead to diminished output power and to damage that could result in total failure of the laser.

According to a further embodiment, the laser apparatus comprises a screening element that is arranged downstream of the emission surface in the emission direction of the light emitted by the at least one laser diode during operation. The screening element has an entrance surface, through which the laser light can enter the screening element. The screening element furthermore has an exit surface, through which the laser light can exit the screening element. The screening element is arranged at least in part in a region in front of the emission surface of the laser diode, in which an optical tweezers effect would take place if the screening element were absent.

The laser apparatus preferably comprises an arrangement with which the optical tweezers effect is prevented entirely or at least in part. The arrangement and the design of the screening element is particularly preferably such that the divergent laser light beam is guided in a medium in which the forces required for the material transport are higher than the forces built up in the field, as a result of which the material transport to the emission surface of the at least one laser diode, which has been caused by the optical tweezers effect, can preferably come to a standstill. An accumulation of deposits on the emission surface can be suppressed by this arrangement. The beam guidance in the screening element consequently takes place with particular preference until the beam divergence is sufficiently great. Depending on the laser beam characteristic, the path of the laser light in the screening element can thus be set by suitably dimensioning the screening element and in particular by a suitable distance of the entrance surface from the exit surface. With the lower irradiance on the light exit side of the screening element, that is to say on the side of the exit surface, a ratio between absorption and desorption can be achieved that no longer leads to accumulation of particles or molecules. Even if absorption effects should still occur, they are particularly preferably considerably less critical at the light exit surface of the screening element than at a laser facet.

Compared to the laser apparatus described here, conventional lasers, in particular those emitting short wavelengths, have so far needed to be encapsulated, which is typically costly. In order to be able to ensure stable operation in the long run, the lasers need to be operated here in a clean, hermetically encapsulated atmosphere. This requires a suitable housing, also referred to below as a package. Currently available solutions are based, for example, on purely inorganic packages, which are resistant to gas and humidity, in the form of TO housings or what are known as “gold boxes”. Such housings consist of combinations with metal, ceramics and glass. Electrical vias are typically implemented by melting contact pins with glass. The packages are closed by mounting metal lids, optionally with windows, by friction welding or resistance welding or soldering.

These types of packages, while being of high quality, are costly and make up a major portion of the high product costs for typical laser packages. In addition, these housings frequently require large installation space and are not suitable for standard SMD mounting methods (SMD: “surface-mounted device”).

By contrast, it is possible using the laser apparatus described here to achieve a cost-effective solution for a robust package of one or more laser diodes that is stable in the long run. The laser apparatus can be used in connection with laser diodes of all performance classes and wavelengths.

According to a further embodiment, the screening element comprises or consists of a material that is transparent to the laser light. The laser apparatus therefore preferably makes possible guidance of the laser beam in a body that is transparent to the wavelength(s) of the laser light. “Transparent” here and below means in particular being preferably as optically transmissive for the laser light as possible.

For visible laser radiation, the screening element can comprise or consist of glass, sapphire or diamond, for example. It is furthermore possible, for example for low laser light outputs, that is to say in the low-power range, as it is known, to use silicones or other plastics. The screening elements can thus for example comprise or consist of one or more plastics, for example silicones, epoxides, acrylates, methyl methacrylates, imides, carbonates, olefins, styrenes, urethanes or derivatives thereof in the form of monomers, oligomers or polymers and furthermore also mixtures, copolymers or compounds therewith, for example epoxy resin, polymethyl methacrylate (PMMA), polystyrene, polycarbonate, polyacrylate, polyurethane or preferably silicone resin, such as polysiloxane or mixtures thereof. For laser light in the infrared range, for example, the screening element can comprise or consist of silicon.

According to a further embodiment, the at least one laser diode is arranged in a non-hermetically sealed environment. In particular, the laser diode, with particular preference the emission surface, can be in direct contact with an atmosphere surrounding the laser apparatus.

According to a further embodiment, the entrance surface of the screening element is located at a distance from the emission surface of the at least one laser diode that is smaller than or equal to 10 μm and with particular preference smaller than or equal to 3 μm. Furthermore, the distance can with particular preference be greater than 0. In other words, a gap which is smaller than or equal to 10 μm or with particular preference smaller than or equal to 3 μm and which can be filled with gas, in particular filled with air, can be located between the emission surface of the at least one laser diode and the entrance surface of the screening element. Such gap widths have proven to be particularly advantageous. An optimum gap width can be derived from the consideration that the optical tweezers effect occurs only at divergent beams. A wave-optical observation of the light exit at a light coupling-out surface shows that the beam divergence directly at the light coupling-out surface is lower than in the spatially remote beam. So, if the screening element is placed sufficiently close in front of the emission surface, the drive force for transporting particles and molecules to the emission surface is significantly diminished.

In particular, the entrance surface of the screening element can be designed such that it does not lie against the emission surface in an interlocking and/or force-fitting manner, as would be the case for example in the case of potting. In contrast to potting or another material arranged using a molding process, the screening element is a self-supporting body that does not adhere to the emission surface.

The screening element can be designed as a plate or a block and preferably have no intended optical effects on the laser light.

Alternatively, the screening element can make beam deflection possible, for example, and be designed as a prism, for example, in which the entrance surface and the exit surface are not located one behind the other along the original beam direction of the laser diode, in contrast to the case of a plate or a block. Furthermore, at least one or both of the entrance and exit surfaces of the screening element can have an at least partially curved shape. The previously described distance between a curved entrance surface and the emission surface in this case is given by the largest distance between said surfaces in the region of the laser light beam.

According to a further embodiment, in the laser apparatus described here, at least two and with particular preference all of the following features are combined:
Guiding the divergent laser light beam exiting the at least one laser diode through the emission surface in a medium of the screening element that is transparent to the wavelength of the laser light.
Guiding the laser light beam in the transparent medium until the energy density of the beam has been reduced to such an extent that critical deposits no longer accumulate at the light exit surface of the screening element.
Placing the screening element so close in front of the emission surface that the beam divergence existing in the remaining gap is not sufficient to allow harmful deposits to occur in the region of the emission surface.

### BRIEF DESCRIPTION OF THE DRAWINGS

Further advantages, advantageous embodiments and developments arise from the exemplary embodiments described below in conjunction with the figures.

In the figures:

FIGS. 1A and 1B show schematic illustrations of a laser apparatus according to one exemplary embodiment, and

FIG. 2 shows a schematic illustration of a comparative example of a laser.

### DETAILED DESCRIPTION

In the exemplary embodiments and figures, elements that are the same, are of the same type, or act in the same way can be provided in each case with the same reference signs. The elements illustrated and their mutual size ratios should not be considered to be true to scale, but rather it is possible that individual elements, for example layers, components, structural components and regions, are depicted with an exaggerated size for the purpose of enabling easier illustration and/or better comprehension.

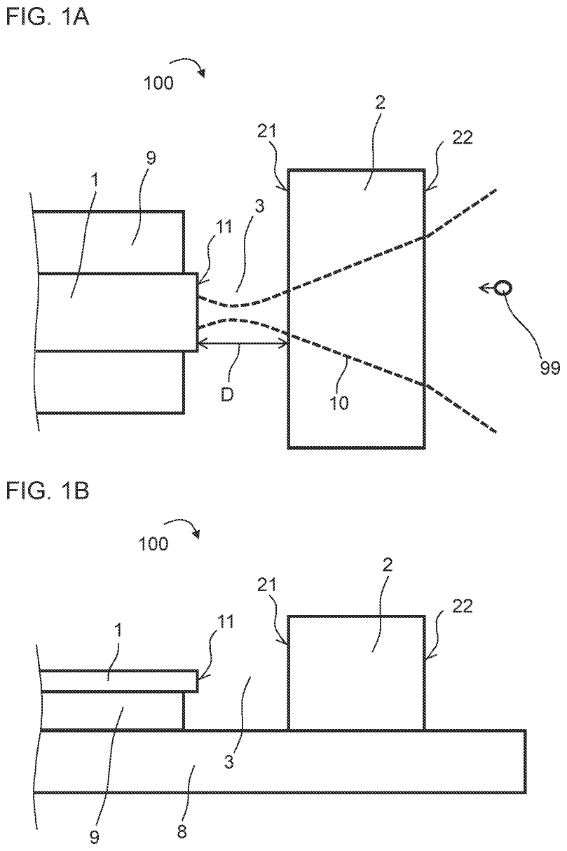

FIGS. 1A and 1B show a top view and a side view of a laser apparatus 100 according to one exemplary embodiment.

The laser apparatus 100 comprises at least one laser diode 1. The laser diode 1 is provided and set up to emit during operation light that is laser light 10 at least when specific threshold conditions are exceeded. The laser diode 1 can in particular be designed as is described in the general part. The laser diode 1 shown in FIGS. 1A and 1B is designed in particular as an edge-emitting semiconductor laser. Alternatively, the laser diode 1 can also be designed as a VCSEL. The following description in this case applies accordingly.

Furthermore, the laser apparatus 100 can comprise a plurality of laser diodes. Even where the following description refers to only one laser diode 1, the corresponding features also apply to a plurality of laser diodes.

Furthermore, the laser apparatus 100 comprises a screening element 2, which is arranged downstream of the laser diode 10 in the emission direction of the laser light 10.

The laser diode 1 and the screening element 2 can be arranged and mounted, as is indicated in FIG. 1B, for example on a carrier 8. In particular, the laser diode 1 and the screening element 2 can be pre-manufactured components that are mounted on the carrier 8. In particular, the screening element 2 is designed not as potting or as a similar element which is only producible on the carrier 8 using a molding process.

As is indicated in FIGS. 1A and 1B, the laser diode 1 can be mounted on the carrier 8 with what is known as a submount 9, which can be made with or from AIN or another material with good thermal conductivity and can be set up for dissipating operating heat from the laser diode 1.

The laser diode 1 has an emission surface 11 on a coupling-out side, from which the laser light 10 generated during operation can exit the laser diode 1. The emission surface 11 forms an interface of the laser diode 1 with which the laser diode 1 adjoins the surrounding medium, which is not an integral part of the laser diode 1. The emission surface 11 can be formed, for example, by a surface of the semiconductor layer sequence of the laser diode 1 or by a surface of a coating on the semiconductor layer sequence. The surrounding medium that adjoins the emission surface 11 can with particular preference be air. With particular preference, the laser diode 1 is arranged in a non-hermetically sealed environment. In particular, the laser diode 1, with particular preference the emission surface 11, can be in direct contact with an atmosphere surrounding the laser apparatus 100 and consequently in direct contact with air.

The screening element 2 comprises or consists of a material that is transparent to the laser light 10. For visible laser radiation, the screening element 2 can comprise or consist of, for example, glass, sapphire or diamond, or a plastic described in the general part. For laser light 10 in the infrared range, for example, the screening element 2 can comprise or consist of silicon. The screening element 2 has an entrance surface 21, which faces the emission surface 11 and through which the laser light 10 enters the screening element 2. The screening element 2 furthermore has an exit surface 22, through which the laser light 10 exits the screening element 2.

The screening element 2 can be designed, as shown, as a plate or a block and preferably have no intended optical effects on the laser light 10. Alternatively, the screening element 2 can make beam deflection possible, for example, and be designed as a prism, for example, in which the entrance surface 21 and the exit surface 22 are not located one behind the other along the original beam direction of the laser diode 1, in contrast to the case of a plate or a block. Furthermore, at least one or both of the entrance and exit surfaces of the screening element can have an at least partially curved shape.

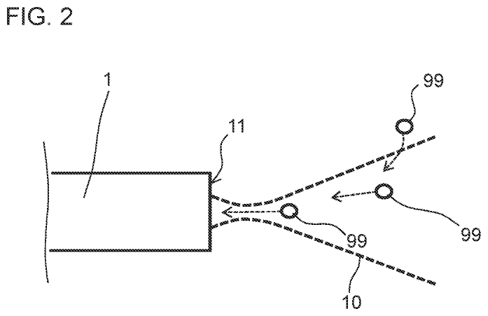

As is described in the general part, the beam divergence of the laser light 10 indicated in FIG. 1A brings about, in conjunction with the energy density of the laser light 10, an optical tweezers effect. FIG. 2 shows a comparative example of a laser diode 1, which does not have a screening element arranged downstream of it and in which particles 99, indicated by way of example by the optical tweezers effect, are transported from the environment in the direction of the emission surface 11. The material deposition on the emission surface 11 that is caused thereby can lead to diminished output power and to damage that can lead to a total failure of the laser.

The laser apparatus 100 according to the exemplary embodiment of FIGS. 1A and 1B comprises an arrangement through which the optical tweezers effect is prevented entirely or at least partially. The arrangement and the design of the screening element 2 is particularly preferably such that the divergent laser light beam is guided in the screening element 2 and thus in a medium in which the forces required for the material transport are higher than the forces built up in the laser light field, as a result of which the material transport to the emission surface 11 of the laser diode 1, which has been caused by the optical tweezers effect, can preferably come to a standstill. An accumulation of deposits on the emission surface 11 can be suppressed thereby. Depending on the laser beam characteristic, the path of the laser light in the screening element 2 can thus be set by suitably dimensioning the screening element and in particular by a suitable distance of the entrance surface 21 from the exit surface 22. With the lower irradiance on the light exit side of the screening element 2, that is to say on the side of the exit surface 22, a ratio between absorption and desorption can be achieved that no longer leads to accumulation of particles or molecules. Even if tweezer effects should still occur, as is indicated in FIG. 1A purely by way of example using the particle 99, they are with particular preference considerably less critical at the light exit surface of the screening element 2 than at the emission surface 11.

The distance D between the emission surface 11 and the entrance surface 21, and thus the width of the gap 3 between the emission surface 11 and the entrance surface 21, is preferably less than or equal to 10 μm and with particular preference less than or equal to 3 μm. Furthermore, the distance D can be greater than 0. As is indicated in FIG. 1A, the typically occurring beam waist can be located in the gap 3 between the emission surface 11 and the entrance surface 21, since in the region thereof there may be a high energy density but no, or only a low, divergence.

A hermetic package free of organic materials for the laser diode 1 is no longer needed in the laser apparatus 100 described here. A hermetic package can be replaced by a considerably simplified arrangement that can in particular protect the at least one laser diode 1 and the arrangement as a whole against mechanical damage and environmental influences. This means costs can be lowered and the space required for the laser apparatus 100 can be significantly smaller compared to conventional laser packages. Moreover, the laser functionality can be more easily and better integrated in applications and modules, which is a considerable advantage given the general trend toward miniaturization.

The features and exemplary embodiments described in conjunction with the figures can, according to further exemplary embodiments, be combined with one another, even if not all combinations have been explicitly described. Furthermore, the exemplary embodiments described in conjunction with the figures may additionally or alternatively have further features in accordance with the description in the general part.

The invention is not restricted to the exemplary embodiments by the description on the basis thereof. Rather, the invention comprises any novel feature and any combination of features, which includes in particular any combination of features in the patent claims, even if this feature or this combination itself is not explicitly specified in the patent claims or exemplary embodiments.

1. A laser apparatus comprising
at least one laser diode having an emission surface via which the laser diode can emit laser light during operation, and
a screening element having an entrance surface which faces the emission surface,
wherein the emission surface of the laser diode is arranged in a non-hermetically sealed environment and the screening element is arranged such that an optical tweezers effect caused by the laser light at the emission surface is prevented entirely or at least partially.

2. A laser apparatus comprising
at least one laser diode having an emission surface via which the laser diode can emit laser light during operation, and
a screening element having an entrance surface which faces the emission surface,
wherein the laser light emitted during operation has a beam waist that is located in a gap between the emission surface and the entrance surface.

3. The laser apparatus as claimed in claim 1, wherein the entrance surface of the screening element has a distance from the emission surface of the at least one laser diode that is smaller than or equal to 3μm.

4. The laser apparatus as claimed in claim 1, wherein the entrance surface of the screening element has a distance from the emission surface of the at least one laser diode that is greater than 0.

5. The laser apparatus as claimed in claim 1, wherein the screening element does not adhere to the emission surface.

6. The laser apparatus as claimed in claim 1, wherein the screening element is transparent to the laser light.

7. The laser apparatus as claimed in claim 1, wherein the entrance surface (21) of the screening element (2) has a distance from the emission surface (11) of the at least one laser diode that is smaller than or equal to 10 μm.

8. The laser apparatus as claimed in claim 1, wherein the emission surface adjoins air.

9. The laser apparatus as claimed in claim 2, wherein the entrance surface of the screening element has a distance from the emission surface of the at least one laser diode that is smaller than or equal to 3 μm.

10. The laser apparatus as claimed in claim 2, wherein the entrance surface of the screening element has a distance from the emission surface of the at least one laser diode that is greater than 0.

11. The laser apparatus as claimed in claim 2, wherein the screening element does not adhere to the emission surface.

12. The laser apparatus as claimed in claim 2, wherein the screening element is transparent to the laser light.

13. The laser apparatus as claimed in claim 2, wherein the entrance surface (21) of the screening element (2) has a distance from the emission surface (11) of the at least one laser diode that is smaller than or equal to 10 μm.

14. The laser apparatus as claimed in claim 2, wherein the emission surface adjoins air.
